(19) United States
(12) Patent Application Publication
(10) Pub. No.: US 2012/0024372 A1
(43) Pub. Date: Feb. 2, 2012

(54) SOLAR OPERATED WATER HEATER

(76) Inventor: Domingo Delgado, Coral Springs, FL (US)

(21) Appl. No.: 12/856,843

(22) Filed: Aug. 16, 2010

Related U.S. Application Data
(63) Continuation-in-part of application No. 12/074,021, filed on Mar. 1, 2008, now Pat. No. 7,793,652.

(51) Int. Cl. H01L 31/04; F24J 2/30; F24J 2/04

(52) U.S. Cl. 136/259; 126/646; 126/643

(57) ABSTRACT

A free-floating, integrated, solar operated water heater appliance, for heating a body of water includes a flotation device for buoyantly supporting the appliance in the body of water. A water heater element, fueled by solar energy, heats water pumped through the heater element by an integral pump, driven by solar energy. A solar energy reflector/container supports the heater element and concentrates solar energy onto the outer surface of the heater element. A parabolic reflector concentrates solar energy onto the inner surface of the heater element. Water is circulated through the heater element and returned, in elevated temperature, to the body of water.

### RELATED US PATENT APPLICATION

This Continuation-In-Part U.S. Application claims priority to Non-Provisional U.S. application Ser. No. 12/074,021, filed Mar. 01, 2008, which is incorporated in its entirety by reference herein.

### FIELD OF THE INVENTION

The present invention relates to solar operated water heating devices, in particular a self-contained, solar operated, buoyant heat absorbent and heat transfer appliance, for heating a controlled fluid, such as water in a swimming pool, for example.

### SUMMARY OF THE INVENTION

The presence and use of a swimming pool as a residential accessory is very great in today's society. In-the-ground swimming pools are very popular as residential accessories, in the warmer parts of the continental United States but are not limited to the warmer climes. Above-the-ground swimming pools are also very popular, especially where the residence is short of land area, for the pool. When the weather is warm and/or the sun is shining, the temperature of the water in the pool tends to warm and being in the pool water appears to be more enjoyable. When weather temperature gets cool and/or cold, use of the pool tends to be limited. In order to extend the use and/or enjoyment of a swimming pool in an environment where the weather becomes cool and/or cold, pool water heater appliances are frequently used. Many pool water heater appliance use natural or propane gas as fuel to heat the water of the pool. Heating the water of the swimming is preferred by many, especially in cool and/or cold weather, when the water in the pool becomes substantially lower in temperature than normal body temperature.

The problem with available pool water heaters is that the pool water heating appliance is large, cumbersome and expensive. The temperature of the water of a swimming pool, whether it is an in-the-ground or an above-the-ground swimming pool, may often be raised substantially above ambient temperature, using presently conventional swimming pool water warming appliances, however, this is often an over-kill and this is wasteful and expensive. It is very often found that the initial cost of the swimming pool water warming appliance is very high and the appliance is costly to run. The over-kill use, that often occurs, is a waste of energy and money. What is needed is a heater for the water of a swimming pool that is initially low in cost and inexpensive to run. The present invention is a self-contained or integrated swimming pool water heating appliance, which is buoyantly floated in the water contained in the swimming pool and uses solar energy to warm the water of the swimming pool.

The present invention is a self-contained, in-the-water appliance of assembled conventional technology, in a novel combination and relationship providing a functionally fashioned solar heat absorbing and heat transfer materials suspended, buoyantly, in an air and water environment for heating water in a controlled environment, such as a swimming pool, for example. Solar heat energy is directed to and/or concentrated on functional elements fabricated from heat absorbing and heat transfer materials, in a contained water environment. The functionally fashioned solar heat absorbing and heat transfer materials, such as heat exchange materials, for example, are exposed to solar rays and absorb heat energy from the sun. The absorbed heat is transferred from the heat exchange unit to the water in contact with the heat exchange unit. The water heated within the heat exchange unit rises, naturally, as the water is heated, initiating a water flow or circulation through the heat exchange unit. In order to ensure a discrete water flow through the heat exchange unit, a water pump means, such as a sump pump, for example, is provided. The input to the water pump means is connected to the unheated body of water adjacent the buoyantly floating water heater so that unheated water, of the contained water, is gently applied to the heat exchange unit of the integrated water heater.

As circulation is initiated, water, of relatively low temperature, flows through the integrated heater element and is heated. The heated water flows out an upper outlet of the water heater, flowing, in cascade fashion, over the exterior surface of the heat transfer element. The flowing, heated water is further heated as the water cascades over the exterior of the heat transfer element. A catch basin or trough is provided at the base of the heat transfer element. One or more water returns, connected to the catch basin, return the collected, heated water to the contained body of water. The returned, heated water causes the temperature of the body of water to rise, appropriately. A preferred embodiment of this invention provides a floating appliance, which consumes solar energy and is essentially cost free to operate.

In a preferred embodiment, the present invention provides a self-contained, free floating water heater that heats water of a body of water by applying direct solar energy and reflected solar energy onto heat exchange elements fabricated from materials that have good to excellent solar energy and heat transfer characteristics. Solar energy is collected and employed to heat water through the vehicle of a heat exchange unit or heat-sink device. A flotation apparatus, which may be in the form of a ring of buoyant material and supporting pedestal, supports the water heater in a partially submerged attitude in an air/water environment, within a controlled body of water.

The heat exchange unit nests in a substantially sealed reflector/container vessel. The vessel also supports a parabolic solar energy reflector between the base of the vessel and the heat exchange unit. The interior wall of the reflector/container vessel receives direct solar energy and reflects the direct solar' energy on to the outer exterior surface of the heat exchange unit, while the parabolic solar energy reflector receives a second direct solar energy and reflects the second direct solar energy on to an inner exterior surface of the heat exchange unit.

Preferably, a reflector/container vessel is supported, buoyantly in a body of water. An inner wall of the reflector/container vessel is fabricated to provide good to excellent solar energy reflection and directional reflection characteristics. Solar energy applied directly from the sun to the surface of the inner wall is reflectively directed to the interior area of the reflector/container vessel. A heat exchange element is nested in the interior area of the reflector/container vessel for receiving solar energy reflected and directed from the inner wall of the reflector/container vessel. The reflected, directed solar energy from the inner wall is applied to the outer surface of the heat exchange element. The heat exchange element is oriented in the interior area of the reflector/container vessel so that the outer surface of the heat exchange element receives solar energy directly from the sun. Thus, the outer surface of the heat exchange element receives a concentration of direct solar energy, from the sun and reflectively directed solar energy from the inner wall of the reflector/container vessel, for heating water passed through the heat exchange element.

A parabolic dish reflector of solar energy provides additional reflected solar energy, reflected on to the inner surface of the heat exchange element. The parabolic dish reflector is contoured and oriented between the reflector/container vessel and the heat exchange element, for receiving solar energy directly from the sun and for reflecting the received solar energy on to the inner surface of the heat exchange element for further heating water passed through the heat exchange element.

Preferably, the heat exchange element is defined by an elongated tube disposed in serpentine configuration, with adjacent exterior walls of the serpentine configuration connected defining a substantially cone-shaped, hollow or chamber walled vessel. The materials from which the heat exchange element is fabricated have good to excellent heat absorbent and/or heat exchange characteristics. The chamber of the heat exchange element has an input or inlet at one end and an output or outlet at the other end. The inlet of the chamber is connected to the output of a submerged pump, for example a sump pump or a low power, low volume water pump, for maintaining a flow of water through the length of the coiled tubing defining the chamber of the heat exchange element. The outlet of the chamber ejects an exiting flow of heated water, in cascade arrangement, over the outer exterior wall of the cone-shaped vessel. The cascading water is further heated by the outer exterior wall of the vessel and is collected by a catch basin coupled to the base of the outer, exterior wall, adjacent an open portion of the vessel. Drains from the catch basin pass through ports in the wall of the reflector/container vessel and return the recovered, heated water to the body of the contained water.

The reflector/container vessel is supported on a pedestal and a flotation means so that the reflector/container vessel floats substantially on the surface of the body of contained water.

A power supply, which may be solar voltaic cells or variable temperature voltaic cells, may be mounted on or adjacent the exterior wall of the reflector/container vessel and connected to provide power to drive a submerged water pump means, for initiating and/or sustaining the flow of water through the heat exchange element. Alternatively, the power supply for the submerged water pump may be a battery, which compliments the self-contained, free flotation characteristic of the invention. If desired, a hard wire line may be used to provide power for the submerged water pump. If a hard or solid wire connection is used to connect the flotation device to residential current, for example, the free flotation characteristic is reduced somewhat, according to the size and length of the wire connection.

In an alternative arrangement the heat exchange element of the invention may be in the form of a hollow walled vessel, defining a chamber, with heat-sink vanes, spanning the width of the chamber, connected between opposing walls. The chamber has an input and an output for passing water through the chamber. The internal vanes connect to opposing walls and receive heat from the walls by conduction. Heat is transferred from the vanes and the walls to water passing through the chamber. The input to the chamber is connected to the output of the pump means for receiving water from the pump. The output from the chamber permits water passed through the chamber to exit the chamber and flowingly cascade over the exterior surface of the outside wall of the hollow walled vessel. One or both of the walls of the hollow walled vessel may be waved, thereby increasing the length and/or area of the surface of the wall without increasing the size of the vessel. The heat-sink vanes may be perforated, thereby increasing the surface area of the vane and thus increasing the heat transfer capability of the vane.

### OBJECTS OF THE INVENTION

It is an object of the invention to provide a self-contained heater accessory for heating water of a swimming pool that buoyantly floats in the body of water to be heated and uses solar energy for warming the water of the pool.

Another object is to provide a self-sufficient heater appliance for heating the water of a swimming pool that uses solar energy to heat the water and buoyantly floats in the body of water to be heated.

Another object is to provide a self-contained appliance, buoyantly floatable in the body of water contained in a swimming pool for heating the water of the swimming pool using solar energy to heat the water and circulate the water through the heating element.

A further object is to provide a heater appliance for the water of a swimming pool which is free floating, within the water to be heated, self sufficient, low in cost to operate, and will not waste energy in over heating the water.

These and other objectives will become apparent after viewing the following drawing showing embodiments of the invention and reading the following description thereof.

### BRIEF DESCRIPTION OF THE FIGURES

FIG. 1 presents a block diagram of the invention;

FIG. 2 presents a perspective view of the heater element container and heat collector of the invention;

FIG. 3 presents a perspective view of an embodiment of the heater element of the invention, connected to a pump means;

FIG. 4 presents a perspective view of a parabolic dish for reflecting solar heat toward the inner surface of the heater element of the invention;

FIG. 5. presents a perspective view of the support pedestal and flotation element for the invention;

FIG. 6 presents a partial cut out, side elevation view of an alternate embodiment of a heater element usable in practicing the invention: and

FIG. 6a presents an exploded view of one embodiment of a heat sink vane useful in practicing the invention using the embodiment represented in FIG. 6.

FIG. 7 presents a perspective view of an alternate embodiment of the solar operated water heater;

FIG. 8 presents a sectioned side elevation view of an enclosed exemplary embodiment of the solar operated water heater;

FIG. 9 presents a sectioned side elevation view of an enclosed exemplary embodiment of the solar operated water heater, including enhanced thermal transfer elements;

FIG. 10 presents a sectioned side elevation view of a liquid enhanced heat exchanger for use in conjunction with the present invention;

FIG. 11 presents an exemplary implementation of the solar operated water heater, placing a plurality of heaters in series;

FIG. 12 presents an exemplary implementation of the solar operated water heater positioning the heater proximate a body of water; and

FIG. 13 presents an exemplary embodiment of a self-contained solar operated water heater utilizing a series of heat exchanging fins for heating a body of water.

### DETAILED DESCRIPTION OF THE INVENTION

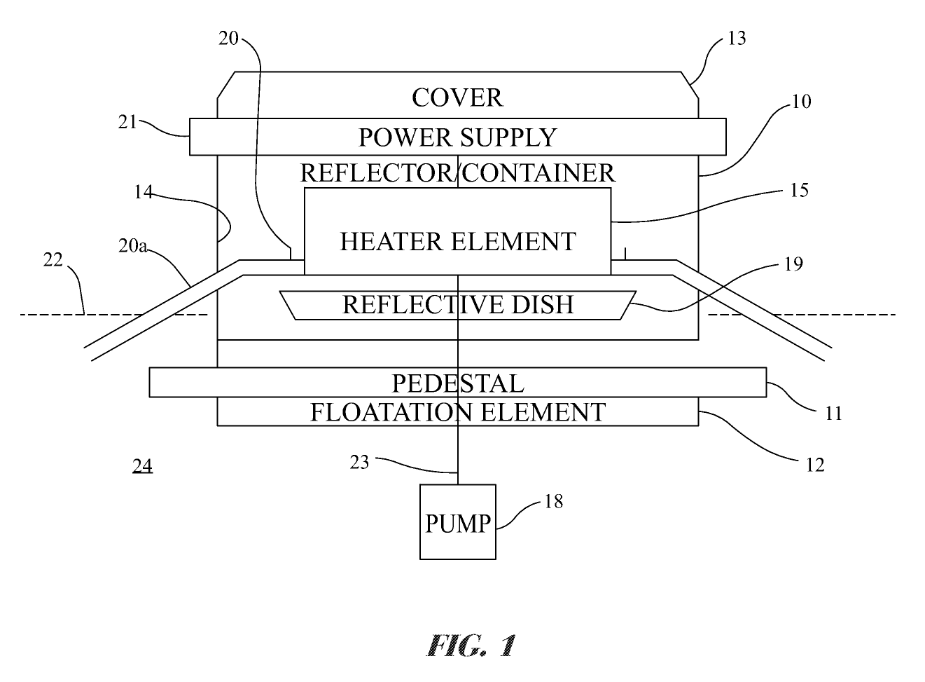

Throughout the several Figures, identical call outs are used to identify identical structure. FIG. 1 is a block diagram representing the invention. Block 10, REFLECTOR/CONTAINER, is supported on block 11, PEDISTAL, which is supported on block 12, FLOTATION ELEMENT. The flotation element holds the invention afloat in a body of water 24, such as a swimming pool, for example. The HEATER ELEMENT, block 15, is supported in the interior of the reflector/container 10, over REFLECTOR DISH, block 19. Block 18, PUMP, is connected with the heater element 15 by a conduit 23, the pump 18 being submerged in the body of water 24. The heater element includes a catch basin 20 and drains 20a. Block 21, POWER SUPPLY, provides power for driving the pump 18, providing a self-sufficient appliance.

The invention is a self-sufficient, buoyantly floated water heater appliance for heating a contained body of water, for example, water in a swimming pool. A reflector/container 10 is held afloat, by a flotation means, in a body of contained water, such as water in a swimming pool, for example. The flotation means comprises a pedestal 11 and a flotation element 12. The pedestal supports the reflector/container 10 and the flotation element supports the pedestal. The flotation element has sufficient buoyancy to lift and maintain a substantial portion of the reflector/container 10 above the surface 22 of the body of water 24. The reflector/container 10 has a cover 13, which is preferably fabricated from materials having characteristics, which are highly transparent to solar rays and/or solar heat and/or solar energy (hereinafter referred to as solar energy). The surface of the interior wall 14 of the reflector/container 10 is fabricated from materials and/or has a finish, which highly reflects, and directs solar energy received from the sun for concentrating and directing the received solar energy on to the outer surface of the heater element 15. The cover 13 is fabricated for passing solar energy and for retaining heat in the interior of the reflector/container 10, generating a greenhouse effect in the enclosed reflector/container vessel. The heater element 15 is preferably fabricated from materials having good to excellent solar energy absorbing characteristics and good to excellent heat transfer characteristics. A submerged water pump 18, such as a sump pump means, for example, secured below the flotation member, has an input connected to the body of water in which the water pump is submerged and has an output connected to the input of the heater element 15. The heater element 15 nests in the interior of the reflector/container 10, over a parabolic dish solar energy reflector 19. The parabolic dish is fabricated from materials, and has a surface having good to excellent solar energy reflection characteristics. The position and contour of the parabolic dish reflector 19 is such so as to reflect solar energy in a concentrated reflection, on to the inner exterior surface of the heater element 15, through the open bottom of the heater element. Water pumped into the input or inlet of the heater element 15 by the pump 18 flows or circulates through the heater element and out the output or outlet of the heater element, cascading over the outer exterior surface of the heater element and into a catch basin or trough 20. The water is heated while the water is in contact with the heater element. The heated water is returned to the body of water in the swimming pool through a drain 20a.

A power supply 21, which is preferably an array of solar cells or photovoltaic cells, is supported on the outer wall of the reflector/container 10. The power supply is connected to the pump 18 for driving the pump. Alternatively, the power supply may be an array of variable temperature voltaic cells supported between the air and water adjacent the outer wall of the reflector/container 10. If desired, a battery may be used as the power supply, the battery supported on the outer wall of the reflector/container 10.

Preferably, the water heater appliance floats buoyantly in the body of water 24 in the swimming pool so that the surface 22 of the water is approximately in juxtaposition with the base or bottom of the reflector/container 10. A conductor 23 defined by a pipe or tubing, provides a conduit for the water pumped from the body of water 24 to the heater element 15 by the pump 18. The conductor 23 also serves as a means for suspending the pump in the body of water 24. A port in the base of the reflector/container permits passage of the conductor 23. The port and conductor for a watertight seal and prevent leakage into the interior of the reflector/container. The conductor 23 also passes through ports in the pedestal 11 and flotation member 12, as well as the parabolic dish 19. Drains 20a, from the catch basin 20, return water from the catch basin to the body of water 24, somewhat below the surface 22 of the water. It will be obvious that water, of ambient temperature, pumped from the body of water by the pump member is forcefully flowed through the heating element. The heating element is heated above ambient temperature by solar energy applied to the surfaces of the heating element. The heating element is a heat exchange unit. As the water flows through the interior of the heating element the flowing water is elevated in temperature, above the ambient temperature of the body of water. The water flows out of the heating element, somewhat elevated in temperature above the ambient of the body of water and cascades over the exterior of the heating element. Cascading the water over the exterior surface of the heating element further elevates the temperature of the water. The twice temperature-elevated water is returned to the body of water, from which it was taken, to raise the temperature of the body of water, appropriately.

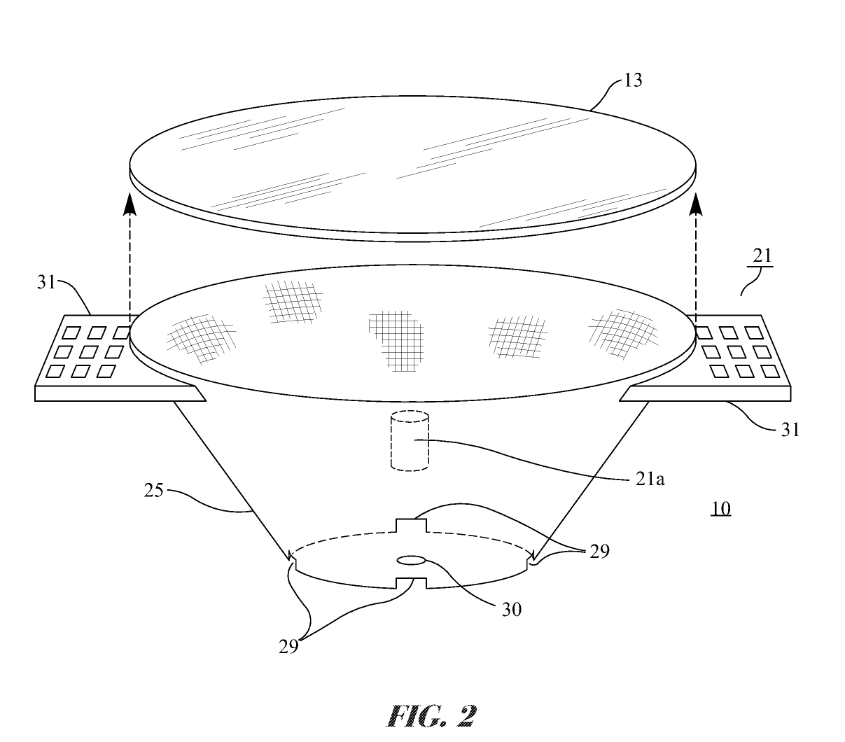

FIG. 2 represents a preferred embodiment of a reflector/container 10 (FIG. 1) usable in practicing the invention. A generally inverted cone-shaped member 25 has the surface of interior walls 14 fabricated for providing good to excellent direction and reflection characteristics for solar energy. The heater element 15 of FIG. 1 is supported in the interior of the reflector/container 10 with ports 29 provided for accepting the drains 20a of the catch basin 20. Preferably, each drain 20a fits into and extend out of a port 29 aligned to receive the drain. Each drain fits in a port in water-tight relationship, keeping water out of the reflector/container interior when the heater element 15 is nested in the reflector/container 10. The drains 20a return water to the body of water 24 somewhat below the surface 20. A port 30 is provided in the base of the reflector/container for passing the conduit 23, in sealed relationship.

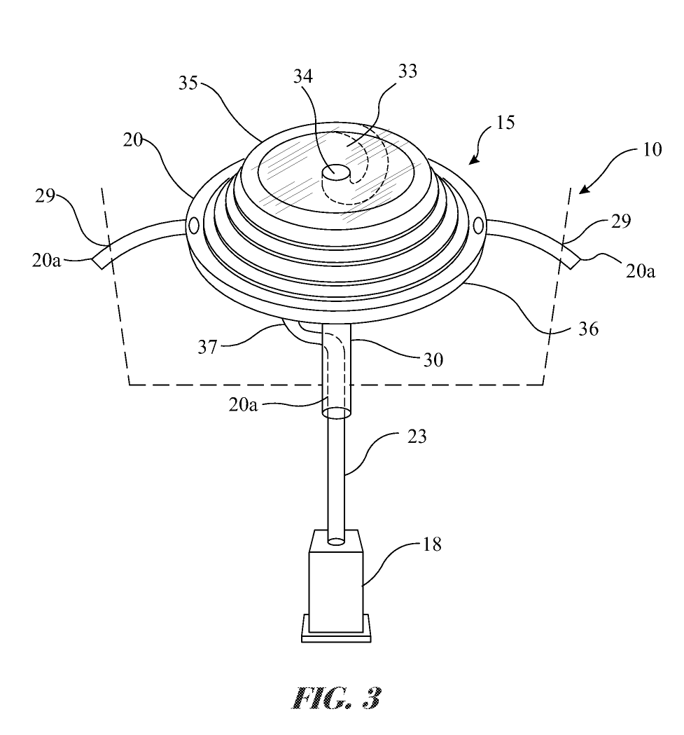

An array 31 “represents a power supply 21 in balanced array supported on the exterior wall 25 of the reflector/container 10. The connection (not shown) between the power supply and the pump (FIGS. 1 and 3) for driving the pump will be apparent to those skilled in the art. The cover or seal 13 for enclosing the reflector/container is fabricated from materials having good to excellent solar energy transmitting and thermal retaining characteristics. When the cover plate 13 is covering the open top of the reflector/container 10 and the heater element 15 is nested in the interior of the reflector/container, solar energy passing through the cover 13 is directly applied to the outer, exterior surface of the heater element 15 and to the interior wall surface 14 of the reflector/container 10. Solar energy applied to the interior wall surface 14 of the reflector/container is reflected and applied to the outer, exterior surface of the heater element 15. The combined direct application of solar energy and reflected application of solar energy on to the outer, exterior surface of the heater element defines a concentrated application of solar energy on the outer, exterior surface of the heater element 15. With the cover 13 fitted to the top of the reflector/container a greenhouse effect is provided. Application of solar energy to the inner exterior surface of the heater element is discussed below.

It may be desired to use an alternate, additional and/or back-up power supply. A battery 21a, represented in broken line form, may be used, if desired, when practicing the invention.

FIG. 3 represents a preferred embodiment of a heater element or heat exchange element, usable when practicing the invention. The heater element 15 is fabricated from tubing materials having good to excellent heat transfer characteristics. The tubing is helically disposed with longitudinal edges of adjacent tubing connected, defining a cone-shaped vessel with a hollow, serpentine chamber within its walls. The top of the cone-shaped vessel is closed 33 and has an outlet 34, which connects with the upper end of the tubing or chamber for ejecting water passed through the chamber, for cascading over the outer wall 35. The outer exterior 35 of the hollow wall defines a semi-tube cascaded wall, which terminates in open configuration 36. The chamber has an inlet 37, which communicates with the conduit 23 extending from the pump 18, for receiving water pumped by the pump. Adjacent the open base of the cone-shaped chambered vessel is a catch basin or trough 20 with drains 20a. The drains extend out ports 29 for supporting the heater element 15 in the reflector/container 10.

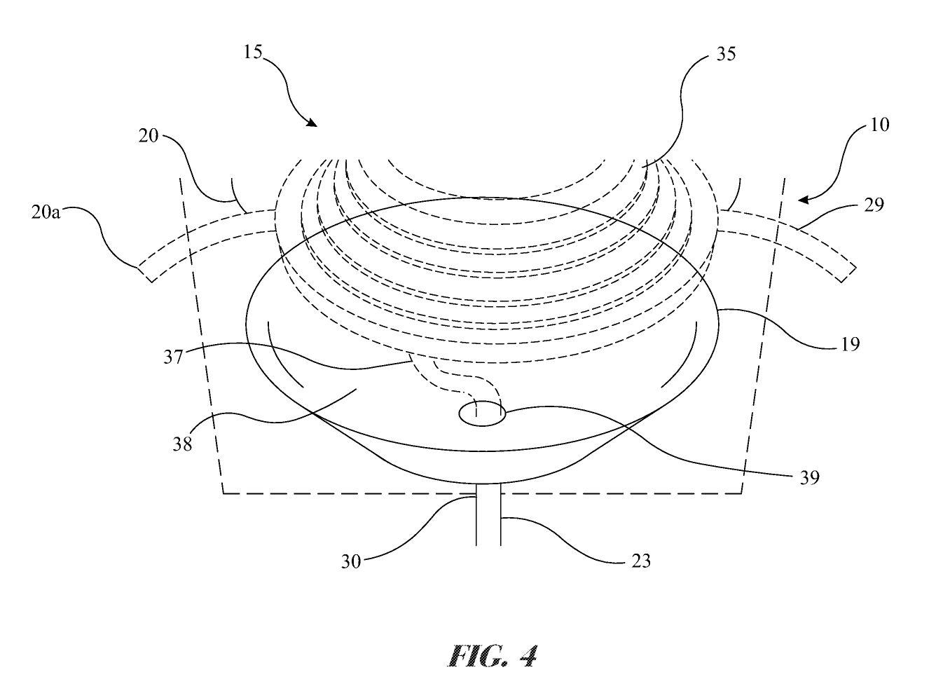

FIG. 4 represents a preferred embodiment of a parabolic dish reflector 19, which is supported in the interior of the reflector/container 10. The heater element 15 (represented in broken line form in FIG. 4) nests in the reflector/container 10 above the parabolic dish reflector 19. The inner exterior surface 38 of the parabolic dish reflector is fabricated and finished for reflecting solar energy. The dish 19 is adapted and oriented to receive, reflect and concentrate solar energy received through the cover 13, on to the inner exterior surface of the heater element 15 through the open bottom of the cone-shaped vessel. The parabolic dish 19 has a port 39 through which the conduit 23 passes to connect with the inlet 37 on the heater element 15.

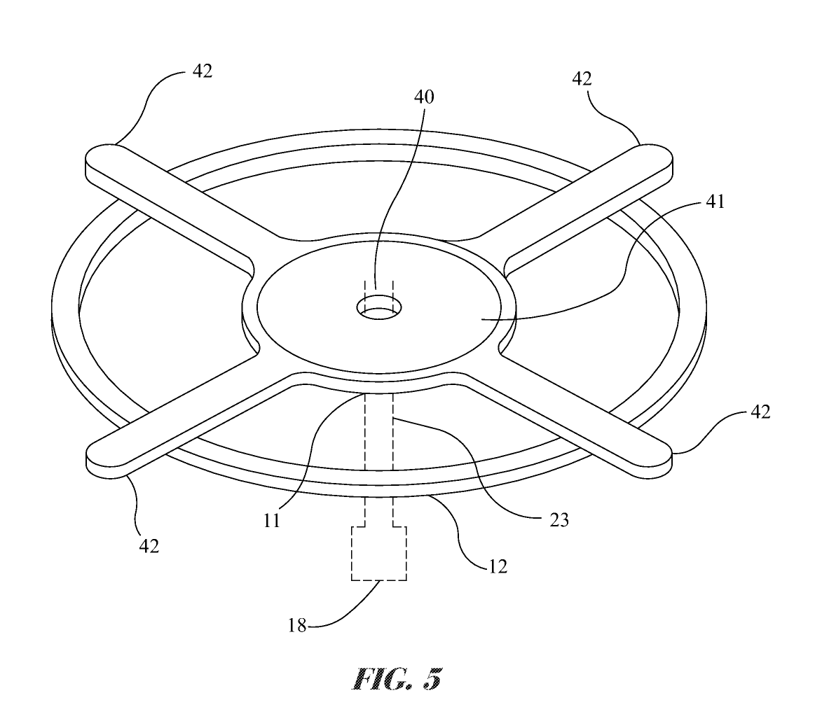

FIG. 5 represents an embodiment of a pedestal 11 and flotation member 12, which holds the invention afloat in a body of water. A port 40 in the base 41 of the pedestal permits passage of the conduit 23 (shown in broken line' form) through the base of the pedestal, for communicating with the inlet to the chamber of the heater element. The pedestal fingers 42 provide support for the reflector/container vessel. The flotation member 12 has sufficient buoyancy, in water, to hold and maintain the appliance afloat in the body of water.

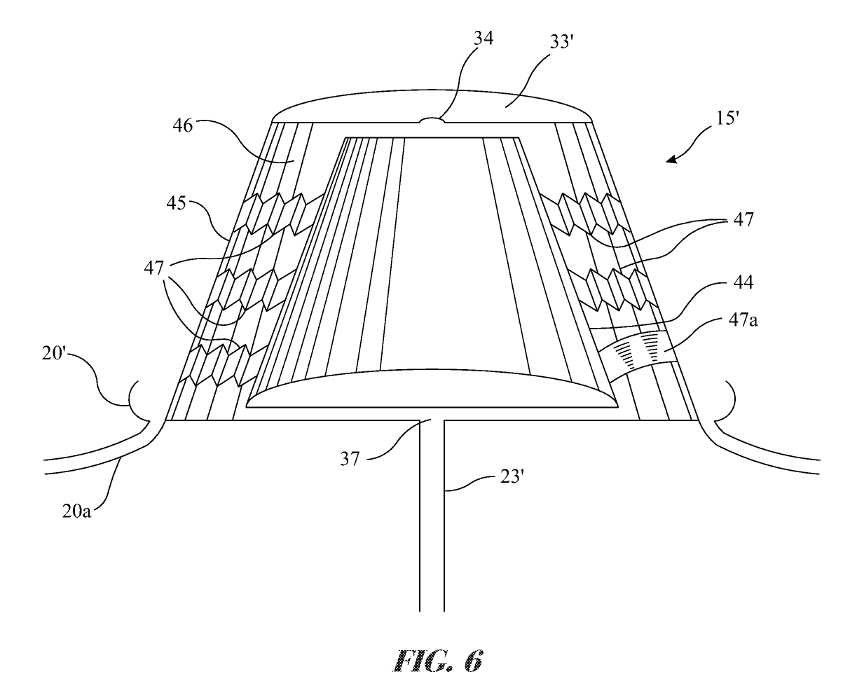

FIG. 6 represents, in cross-section elevation view, an alternate structure heat exchange element 15′, which may be used when practicing the invention, in substitution for the preferred embodiment. A hollow walled inverted cone-shaped vessel is defined by inner wall 44 and outer wall 45, defining a chamber 46. Heat-sink vanes 47 and 47a are secured, at their respective opposite ends, to opposing walls of the chamber. Although a plurality of vanes is represented, a single elongated vane may be used, if desired. Although heat transfer vanes are represented as spanned across the interior of a chamber, the structure may be reversed, and the vanes may be exposed to solar energy and a tube or tubes may pass through the vanes. The vanes are, fabricated from materials having good to excellent heat transfer characteristics. The vanes 47 and 47a receive heat from walls 44 and 45, via conduction. The walls are heated by solar energy, as previously discussed. Water pumped through conduit 23′ flows through the chamber 46, coming in contact with the vanes 47, 47a, which transfer heat to the water. Water flows out the outlet 34, across the closed top 33′ and down the outer wall 45 to the catch basin 20′ and out the spout 20a′. The inner exterior surface of wall 44 may be heated by a solar energy reflecting dish, such as represented in FIG. 4 and disposed as discussed above.

FIG. 6a represents, in cut-out view, a heat transfer vane, such as 47 that is connected to the spaced walls 44 and 45. The heat transfer vane has holes, such as 48 and/or 49, which increase the surface of the vane and increase the heat exchange capability of the vane. The vane is fabricated from materials having good to excellent heat transfer characteristics.

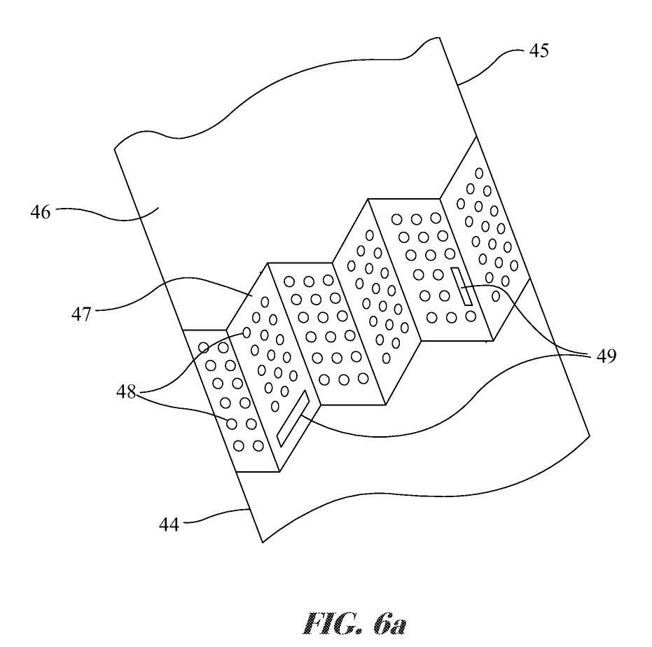

FIG. 7 represents a self-sufficient, buoyantly floated water heater appliance 5. The illustration includes a partial cut away section for clarity of the operational components. The self-sufficient, buoyantly floated water heater appliance 5 includes a generally inverted cone-shaped member 25 having an exterior wall (identified by the leader line reference to 25) and an interior wall surface 28. The exterior can be of any supportive material. The interior is preferably of a reflective material, focusing sunlight 60 onto a heater element 15. The self-sufficient, buoyantly floated water heater appliance 5 includes a solar panel (such as the array 31 of FIG. 2) for converting solar energy from the sunlight 60 to electrical power. One such means would be accomplished by integrating a photovoltaic material into the array 31 (FIG. 2). The generated power would be stored within a battery (such as the battery 21a of FIG. 2). The stored power is used to operate any electrically operated device such as a pump 18.

Pump 18 drives flow of the fluid, collecting cold or source water 50 from a body of water 24 via a intake conduit 23, transferring the water through the heat exchanger 15 and returning the water as heated water 52 to the body of water 24. The water can flow in any manner over, through, across, and the like, in communication with the heat exchanger 15 to transfer heat from the heat exchanger to the water 50. In the exemplary embodiment, the water 50 is discharged through an outlet port 34 and over an exterior surface of the heat exchanger 15. The heated water 52 continues through drains 20a, returning to the body of water 24. A flotation element 12 can be integrated into the self-sufficient, buoyantly floated water heater appliance 5, allowing the user to place the appliance 5 into the body of water 24. The heat exchanger 15 and other components can be assembled to a base 41. The base 41 is supported by a plurality of pedestal fingers 42 extending radially from the base. The plurality of pedestal fingers 42 are placed upon or assembled to the floatation element 12, providing floating support to the assembly. Although the fingers 42 are shown as being radially arranged, it is understood any support interface design can be provided between the elements of the appliance 5 and the floatation element 12. Since the power is self contained within the appliance 5 and regenerating via a solar power sourcing system integrated therein, the appliance 5 is not tethered via any power cord, requiring any recharging, and the like.

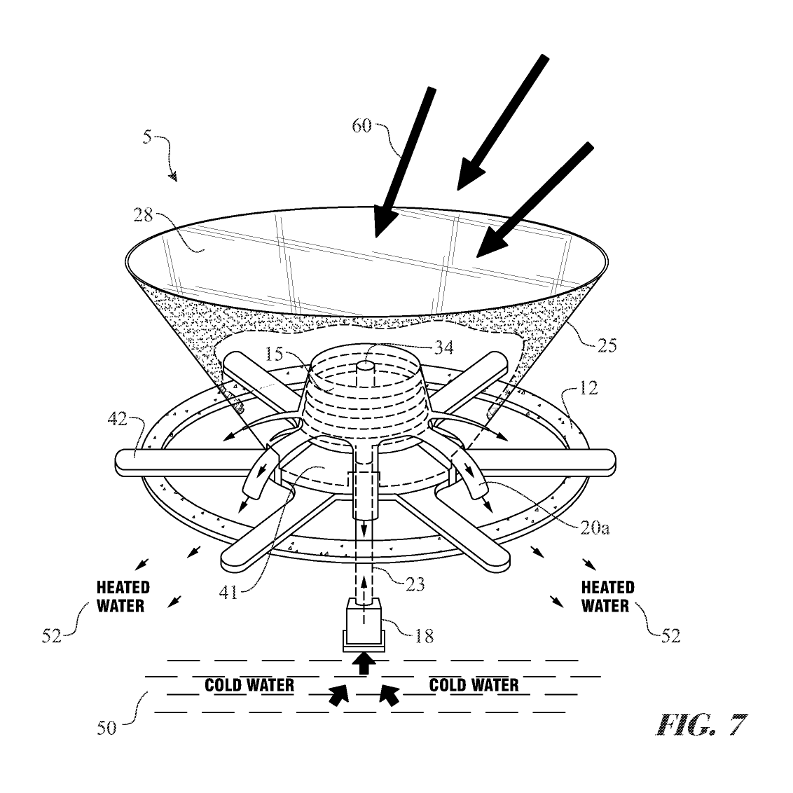

A first alternate exemplary embodiment, referred to as a portable water heater 100, is illustrated in FIG. 8. The portable water heater 100 includes a saucer shaped enclosure comprising a transparent cover 102 and a reflective basin 104, together forming an interior volume 108. It is desirable that the transparent cover 102 be fabricated of a lens having focal intensification properties. The saucer shaped enclosure is preferably of a watertight assembly or other means providing buoyancy to the portable water heater 100. The interior surface 106 is preferably fabricated having a reflective material provided thereon. A heat exchanger 110 is mounted within the interior volume 108, oriented and located to optimize the absorption of energy from the sun from both the transparent cover 102 and the reflection from the interior surface 106. The interior surface 106 of the reflective basin 104 is shaped to direct the solar energy at the heat exchanger. The reflective basin 104 can be a parabolic dish, a parabolic trough, an inverted pyramid, and the like. The heat exchanger 110 includes a heat exchanger core 112 for transferring the absorbed heat to a fluid. Optional heat sinks 114 the can be attached to the heat exchanger 110 to optimize heat transfer.

Fluid is driven through the heat exchanger 110 by an electrically operated pump 120. The pump 120 is powered by stored electrical power (such as via a battery 21a of FIG. 2) or electrical power directly obtained from the sun. The pump 120 draws water in through a supply conduit intake port 123 located at a free end of a supply conduit 122, wherein the supply conduit intake port 123 is inserted into the body of water 24. The supply conduit 122 is connected to the pump 120 at a pump intake port 121, providing fluid communication therebetween. A heat exchanger supply conduit 124 is provided in fluid communication between the pump 120 and the heat exchanger 110 for transferring the fluid from the pump 120 to the heat exchanger 110. A first end of the heat exchanger supply conduit 124 is connected to a pump discharge port 125 of the pump 120, and a second, opposite end is connected to a heat exchanger intake port 111 of the heat exchanger 110. The fluid pressure generated by the pump 120 directs the fluid to travel in thermal communication with the heat exchanger 110, either through the heat exchanger core 112 (for internal passageways) or across an exterior surface of the heat exchanger core 112 (for external fluid paths over an exterior surface). A heat exchanger discharge conduit 126 is provides fluid communication between the heat exchanger 110 and the body of water. The heat exchanger discharge conduit 126 comprises a first end, which is connected to a heat exchanger discharge port 113 of the heat exchanger 110 and a second, free end having a heat exchanger discharge conduit return port 127 for returning heated fluid to the body of water.

Sunlight passes through the transparent cover 102 and is redirected towards the heat exchanger 110 by the shape of the transparent cover 102. The transparent cover 102 can additionally be shaped to magnify the intensity or focal location of the light to enhance the heating process. The sunlight can be reflected towards the heat exchanger 110 by the reflective material applied to the interior surface 106.

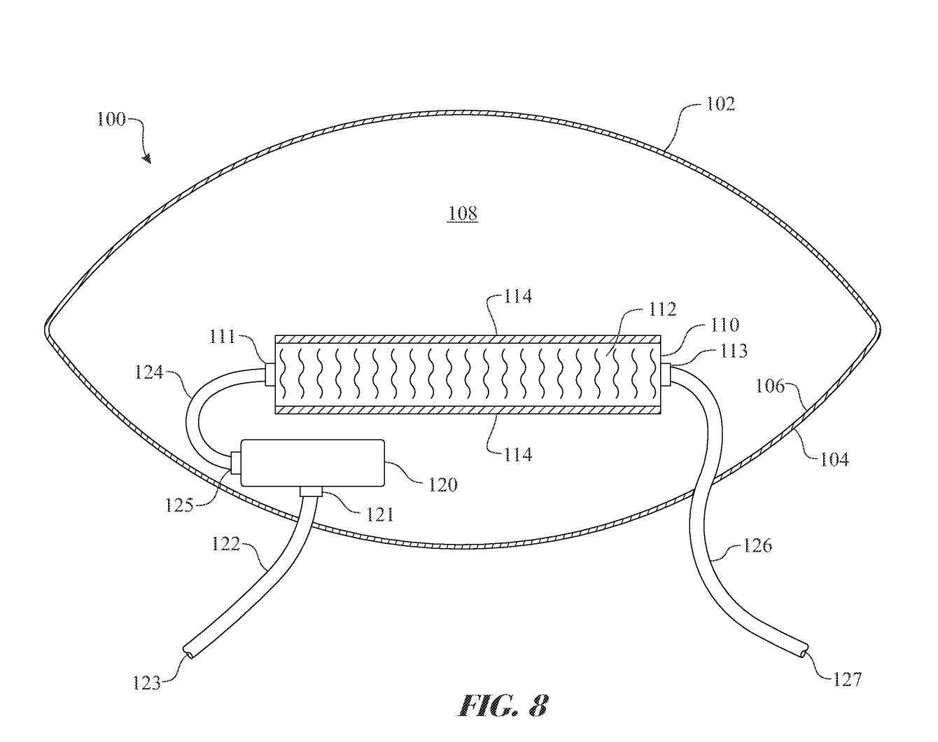

A second alternate exemplary embodiment, referred to as a portable water heater 200, is illustrated in FIG. 9. Like features of the portable water heater 200 and portable water heater 100 are numbered the same except preceded by the numeral ‘2’. A fresnel lens 230 or any other focal lens is integrated into the portable water heater 200 to optimize the heating process. The fresnel lens 230 can be embedded within the interior volume 208 or integrated into the transparent cover 202. The temperature within the interior volume 208 commonly rises as a result of the focused sunlight. A series of spaced apart heat exchanger fins 216 can be thermally coupled to the heat exchanger core 212 to collect the heat generated within the interior volume 208 and transfer the heat energy to the heat exchanger core 212.

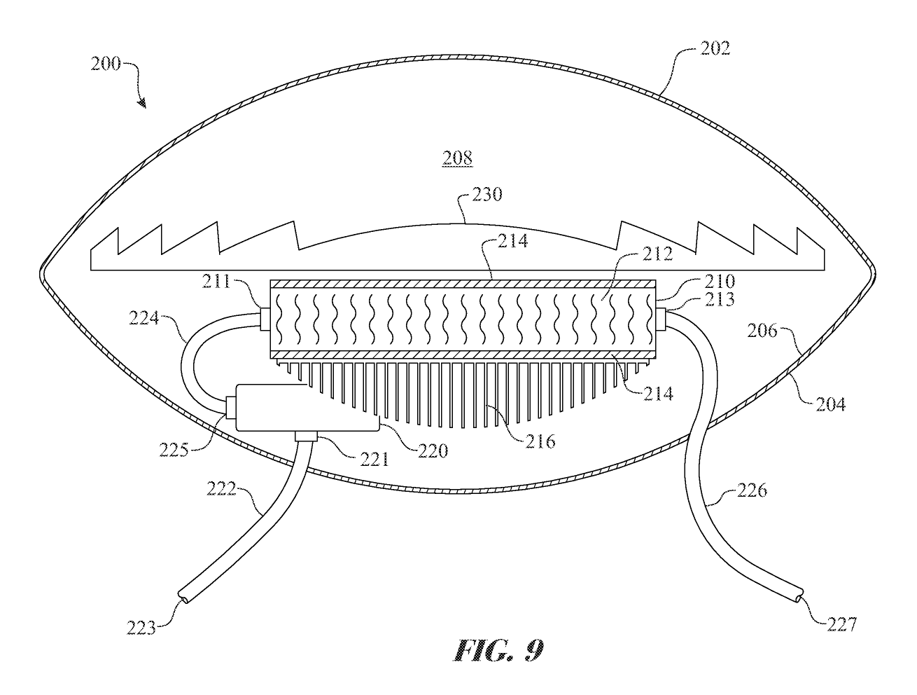

The efficiency of the portable water heater 5, 100, 200, can be improved by incorporating a fluid enhanced heat exchanger 300 therein. An exemplary fluid enhanced heat exchanger 300 is illustrated in FIG. 10. The fluid enhanced heat exchanger 300 includes a heat exchanger 310 comprising a heat exchanger core 312. Fluid is provided to the heat exchanger core 312 by a heat exchanger supply conduit 324, and returned to the body of water by a heat exchanger discharge conduit 326. An optional heat sink 314 can be provided along any section of an outer surface of the heat exchanger core 312 for optimizing thermal transfer. A fluid reservoir 340 is provided in thermal communication with the heat exchanger core 312. The fluid reservoir 340 contains stored thermal transfer liquid 342 and/or stored gas 344. The enclosed medium 342, 344 absorbs heat from the surrounding environment and transfers the thermal energy to the heat exchanger core 312, directly to the passing fluid, or both. Examples of the retained fluid include water, Ethylene glycol (commonly known as antifreeze), ammonia, and the like.

Ammonia is heated to its boiling point in a separate sealed container that has had the air removed and replaced with a small amount of ammonia. The ammonia must be in a sealed container below or in a separate sealed compartment below the heating elements. When the ammonia is heated to its boiling point the vapor that rises is super heated (kind of like steam, but hotter) thus the top of the container, containing the ammonia becomes super heated which in turn heats the heating elements through conduction (direct contact with the top of the ammonia container).

Glauber's salt (sodium sulfate decahydrate, Na₂SO₄-10H₂O) can be included in the interior volume 108 and/or the fluid reservoir 340 in contact with the heat exchanger 110. The Glauber's salt absorbs heat and becomes molten. When the Glauber's salt converts into the molten state, the salt increases the retention of heat over a longer period of long time and distributes the heat evenly.

The efficiency of the portable water heater 5, 100, 200, can be improved by reducing the pressure within the interior volume 108. Alternately, the heat exchanger 110 can be placed within a sealed enclosure, whereby the efficiency can be enhanced by reducing the pressure within the sealed enclosure about the heat exchanger 110.

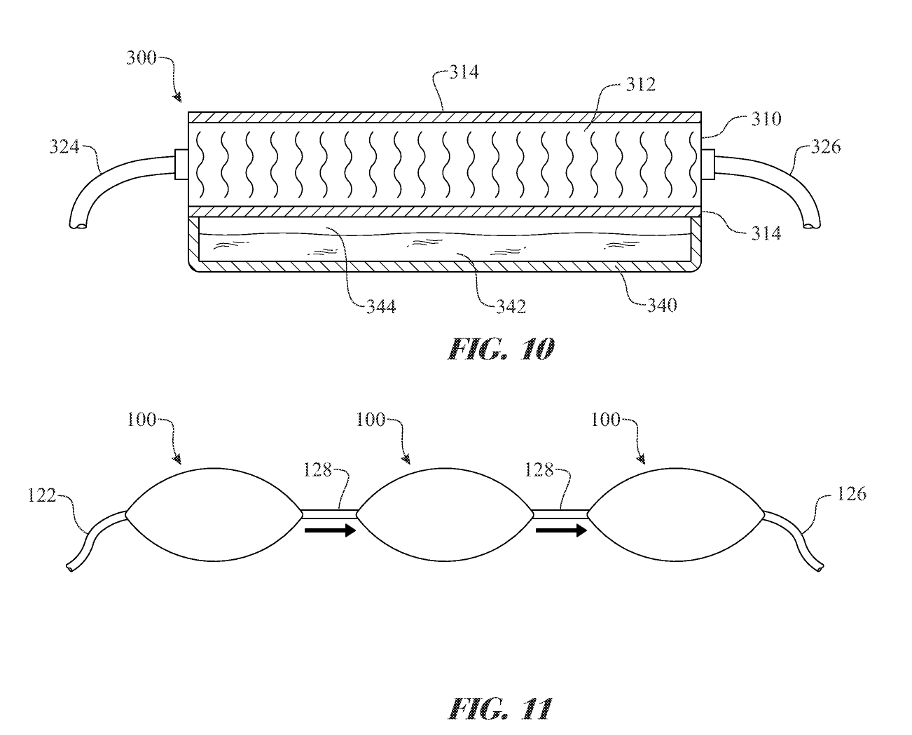

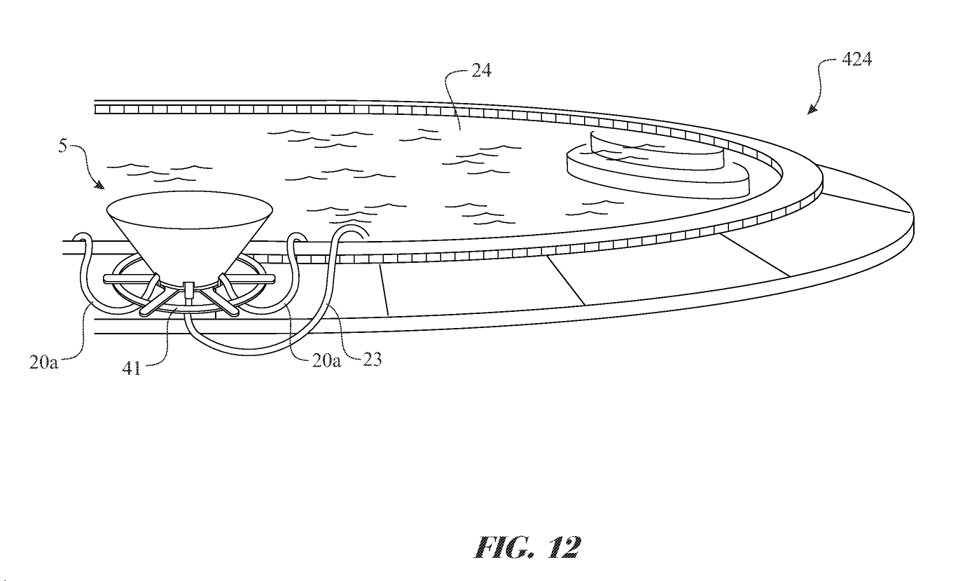

The portable water heater 100, 200 can be sized to service a predetermined volume of water. To optimize manufacturing costs, size, flexibility, and the like, a plurality of portable water heaters 100, 200 can be arranged in series, as illustrated in FIG. 11 or in parallel (well understood by those skilled in the art). A plurality of portable water heaters 100, 200 can be provided in fluid communication via a heat exchanged transfer conduit 128 in any arrangement, including in series, in parallel, or in combination thereof. Source fluid would be obtained from the body of water through the supply conduit 122 and returned to the body of water through the heat exchanger discharge conduit 126.

An exemplary application of the portable water heater 100, 200, is for heating body of water 24 within a swimming pool 424. The self-sufficient, buoyantly floated water heater appliance 5 can be placed upon an edge of the swimming pool 424 as illustrated or floating within the swimming pool 424. Source water is obtained through the conduit 23, heated within the self-sufficient, buoyantly floated water heater appliance 5 and returned as heated water through the drains 20a. The drains can be provided as removable hoses, allowing the water to simply run off the heater element 15 or be directed to a desired, remote discharge location. The self-sufficient, buoyantly floated water heater appliance 5 can be placed onto the body of water, whereby the base 41 would support the apparatus on top of the body of water 24.

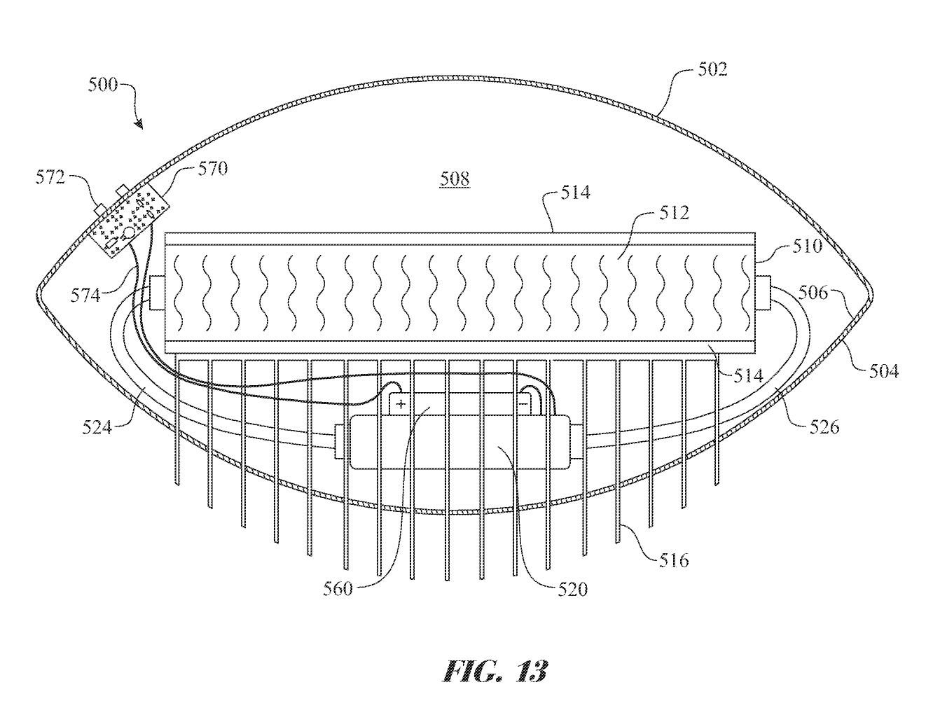

The previously disclosed embodiments transfer the fluid across a heat exchanger and return the heated fluid to the body of water 24. Alternately, apparatus can transfer thermal energy directly into the body of water 24 by utilizing a self-contained solar operated water heater 500. An exemplary version of the self-contained solar operated water heater 500 is illustrated in FIG. 13. Like features of self-contained solar operated water heater 500, and the portable water heater 100, 200 are numbered the same except preceded by the numeral ‘5’. Modifications to create the self-contained solar operated water heater 500 include extending the heat exchanger fins 516 through the reflective basin 504 providing sufficient surface area external to the reflective basin 504 to heat the surrounding water. This exemplary embodiment reduces the need for transferring the source water into and through the heat exchanger 510. The heat exchanger 510 can be solid material or fluid based. A fluid based system includes a heat exchanger supply conduit 524 and a heat exchanger discharge conduit 526 in providing fluid communication between a pump 520 and a heat exchanger core 512, thus creating a closed loop system. Power can be provided to the pump 520 by a stored power source 560, a solar energy conversion device, or combination thereof A controller circuit board 570 can be integrated into the self-contained solar operated water heater 500, allowing for intelligent control and operation of the system. Wiring 574 provides electrical power and/or signal communication between the controller circuit board 570, the stored power source 560, and the pump 520. A user control interface 572 is in signal communication with the controller circuit board 570, providing a user interface. The controller circuit board 570 can include a thermal sensing circuit coupled to a thermal sensor in thermal communication with the heat exchanger core 512 or the fluid therein, for determining the temperature of the fluid. The thermal sensing circuit would operate the pump 520 when the temperature is above or within a predetermined range. It is recognized that a similar circuit can be integrated within any of the embodiments presented herein.

In the foregoing description of the invention, reference to drawings, certain terms have been used for conciseness, clarity and comprehension. However, no unnecessary limitations are to be implied from or because of the terms used, beyond the requirements of the prior art, because such terms are used for descriptive purposes and are intended to be broadly construed. Furthermore, the description and illustration of the invention are by way of example, and the scope of the invention is not limited to the exact details shown, represented, suggested or described.

Having now described a preferred embodiment of the invention in terms of features, discoveries and principles along with certain alternative structure and suggested changes, other changes that may become apparent to those skilled in the art may be made, without departing from the scope of the invention defined in the appended claims.

What is claimed is:

1. A water heater appliance, said water heater, appliance comprising:
an enclosure comprising a transparent cover assembled to a base forming an interior volume;
a parabolic solar energy reflector provided within said interior volume of said enclosure;
a heat exchanger mounted within said interior volume of said enclosure, said heat exchanger being located at a focal location of said transparent cover and a focal location of said parabolic solar energy reflector;
a solar energy converter integrated onto said enclosure in a location exposed to sunlight, said solar energy converted provided for converting solar energy to electrical energy; and
an electrically operated pump operated by said electrical energy from said solar energy converter, wherein said electrically operated pump is in fluid communication with said heat exchanger for directing a fluid to travel in thermal communication with said heat exchanger.

2. A water heater appliance as recited in claim 1, said water heater appliance further comprising:
a supply conduit having an intake port at a free end for insertion into a body of water and a pump port in fluid communication with an intake port of said pump.

3. A water heater appliance as recited in claim 2, said water heater appliance further comprising:
a discharge conduit having a return port at a free end for discharging heated water into a body of water and a pump port in fluid communication with a discharge port of said pump.

4. A water heater appliance as recited in claim 1, said water heater appliance further comprising:
a lens shaped and located to focus solar energy towards said heat exchanger.

5. A water heater appliance as recited in claim 1, wherein said fluid travels through said heat exchanger.

6. A water heater appliance as recited in claim 1, wherein said fluid travels over an external surface of said heat exchanger.

7. A water heater appliance as recited in claim 1, said water heater appliance further comprising:
a plurality of heat exchanger fins extending outward from and in thermal communication with said heat exchanger.

8. A water heater appliance, said water heater appliance comprising:
an enclosure comprising a transparent cover assembled to a base forming an interior volume, wherein said enclosure is watertight and buoyant;
a parabolic solar energy reflector provided within said interior volume of said enclosure;
a heat exchanger mounted within said interior volume of said enclosure, said heat exchanger being located at a focal location of said transparent cover and a focal location of said parabolic solar energy reflector;
a solar energy converter integrated onto said enclosure in a location exposed to sunlight, said solar energy converted provided for converting solar energy to electrical energy; and
an electrically operated pump operated by said electrical energy from said solar energy converter, wherein said electrically operated pump is in fluid communication with said heat exchanger for directing a fluid to travel in thermal communication with said heat exchanger.

9. A water heater appliance as recited in claim 8, said water heater appliance further comprising:
a supply conduit having an intake port at a free end for insertion into a body of water and a pump port in fluid communication with an intake port of said pump.

10. A water heater appliance as recited in claim 9, said water heater appliance further comprising:
a discharge conduit having a return port at a free end for discharging heated water into a body of water and a pump port in fluid communication with a discharge port of said pump.

11. A water heater appliance as recited in claim 8, said water heater appliance further comprising:
a lens shaped and located to focus solar energy towards said heat exchanger.

12. A water heater appliance as recited in claim 8, wherein said fluid travels through said heat exchanger.

13. A water heater appliance as recited in claim 8, wherein said fluid travels over an external surface of said heat exchanger.

14. A water heater appliance as recited in claim 8, said water heater appliance further comprising:
a plurality of heat exchanger fins extending outward from and in thermal communication with said heat exchanger.

15. A water heater appliance as recited in claim 8, wherein a pressure within the interior volume of the enclosure is reduced.

16. A water heater appliance, said water heater appliance comprising:
an enclosure comprising a transparent cover assembled to a base forming an interior volume;
a parabolic solar energy reflector provided within said interior volume of said enclosure;
a heat exchanger mounted within said interior volume of said enclosure, said heat exchanger being located at a focal location of said transparent cover and a focal location of said parabolic solar energy reflector;
a solar energy converter integrated onto said enclosure in a location exposed to sunlight, said solar energy converted provided for converting solar energy to electrical energy;
an electrically operated pump operated by said electrical energy from said solar energy converter, wherein said electrically operated pump is in fluid communication with said heat exchanger for directing a fluid to travel in thermal communication with said heat exchanger; and
a stored thermal transfer liquid disposed within at least one of a fluid reservoir in thermal communication with said heat exchanger and within said enclosure, wherein said stored thermal liquid enhances a heating process.

17. A water heater appliance as recited in claim 16, said water heater appliance further comprising:
a supply conduit having an intake port at a free end for insertion into a body of water and a pump port in fluid communication with an intake port of said pump.

18. A water heater appliance as recited in claim 17, said water heater appliance further comprising:
a discharge conduit having a return port at a free end for discharging heated water into a body of water and a pump port in fluid communication with a discharge port of said pump.

19. A water heater appliance as recited in claim 16, said water heater appliance further comprising:
a lens shaped and located to focus solar energy towards said heat exchanger.

20. A water heater appliance as recited in claim 16, wherein said fluid travels through said heat exchanger.

21. A water heater appliance as recited in claim 16, wherein said fluid travels over an external surface of said heat exchanger.

22. A water heater appliance as recited in claim 16, said water heater appliance further comprising:
a plurality of heat exchanger fins extending outward from and in thermal communication with said heat exchanger.
